(19) United States
(12) Patent Application Publication
(10) Pub. No.: US 2021/0215982 A1
(43) Pub. Date: Jul. 15, 2021

(54) ARRAY SUBSTRATE, DISPLAY PANEL, AND DISPLAY DEVICE

(71) Applicant: HON HAI PRECISION INDUSTRY CO., LTD., New Taipei (TW)

(72) Inventors: SHIANG-RUEI OUYANG, New Taipei (TW); WEI-CHENG CHEN, New Taipei (TW)

(21) Appl. No.: 16/857,580

(22) Filed: Apr. 24, 2020

(30) Foreign Application Priority Data
Jan. 11, 2020 (CN) 202010028529.X

(51) Int. Cl. G02F 1/1362; G06F 3/041; H04N 5/225; H01L 27/12; G02F 1/1343; G02F 1/1333; G02F 1/1339; G02F 1/1368; G02F 1/1335

(52) U.S. Cl. CPC G02F 1/136286; G06F 3/0412; H04N 5/2253; G06F 3/04166; H01L 27/124; G02F 1/133514; G02F 1/13338; H01L 27/1248; G02F 1/13392; G02F 1/1368; G02F 1/133512; G02F 1/134309

(57) ABSTRACT

An array substrate which can carry a camera in a camera area seamlessly surrounded by a display area is disclosed, the camera area defines a transparent area, a first routing area adjacent to the transparent area, and a second routing area surrounding the first routing area. The array substrate includes a first substrate, a first conductive layer, a second conductive layer, a common electrode layer, a third conductive layer, a planarization layer, and a photo spacer. The planarization layer in the transparent area is in direct contact with the first substrate. The photo spacer is in the first routing area. The third conductive layer is around the transparent area and the first routing area.

### FIELD

The subject matter herein generally relates to displays, in particular, to an array substrate, a display panel using the array substrate, and a display device using the display panel.

### BACKGROUND

Display devices such as mobile phones, tablets, and the like, are multifunctional, and combine components for functions to be available. Display devices incorporating a camera are widely produced and used.

Taking an array substrate including a plurality of wires in a display device as an example, an area for one or more cameras must be found on the array substrate. However, the camera area affects arrangement of the wires of the array substrate and even the performance of the display device.

Therefore, there is room for improvement in the art.

### BRIEF DESCRIPTION OF THE DRAWINGS

Implementations of the present disclosure will now be described, by way of embodiment, with reference to the attached figures.

FIG. 1 is a top planar view of an array substrate according to an embodiment.

FIG. 2 is a cross-sectional view along line II-II of FIG. 1.

FIG. 3 is a schematic view showing an arrangement of scan lines and data lines of the array substrate of FIG. 1.

FIG. 4 is an enlarged view of portion IV of FIG. 3.

FIG. 5 is a schematic view showing an arrangement of touch lines of the array substrate of FIG. 1.

FIG. 6 is an enlarged view of portion VI of FIG. 5.

FIG. 7 is a cross-sectional view of a display panel according to an embodiment.

FIG. 8 is a cross-sectional view of a display device according to an embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”. The term “circuit” is defined as an integrated circuit (IC) with a plurality of electric elements, such as capacitors, resistors, amplifiers, and the like.

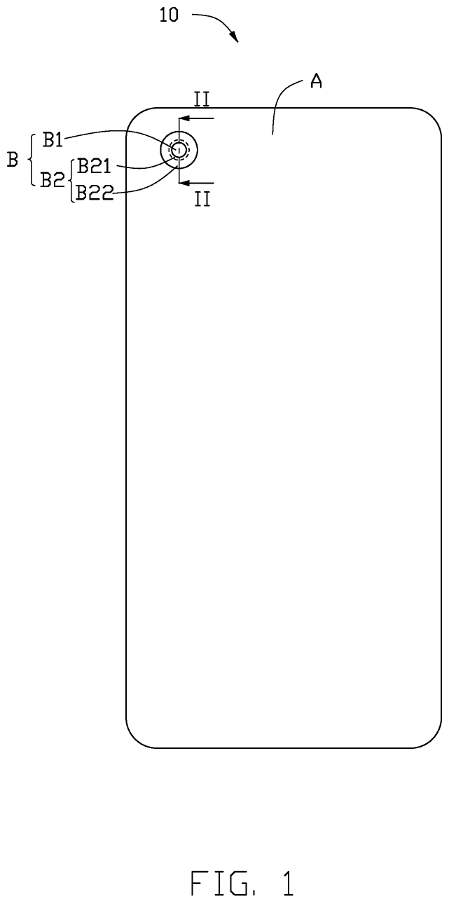

FIG. 1 shows an array substrate 10 according to an embodiment. The array substrate 10 defines a display area A and a camera area B which is completely surrounded by the display area A. The camera area B defines a transparent area B1 and a routing area B2 surrounding the transparent area B1. The routing area B2 includes a first routing area B21 adjacent to and surrounding the transparent area B1 and a second routing area B22 surrounding the first routing area B21. The camera area B is transparent and allows light to pass through. The camera area B and the transparent area B1 are substantially circular. The routing area B2 is substantially annular. In other embodiments, the camera area B may have other shapes. For example, oval, polygonal, and the like.

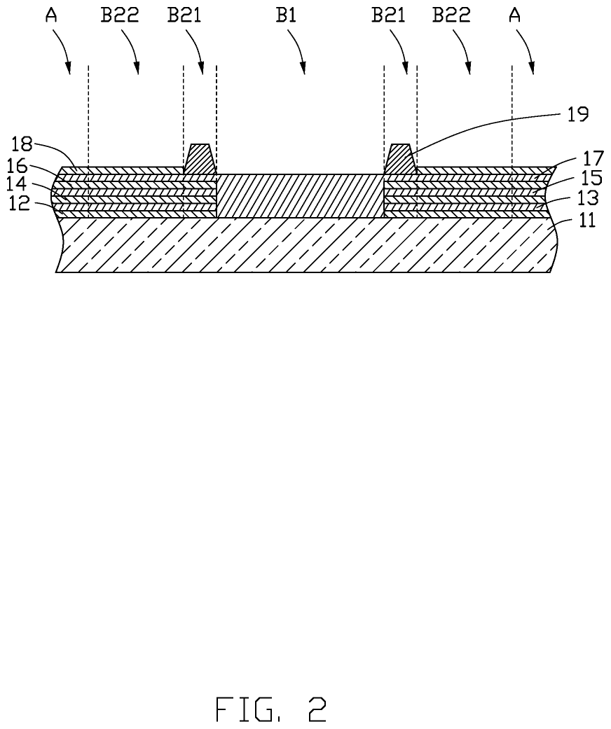

As shown in FIG. 2, the array substrate 10 includes a first substrate 11, a first conductive layer 12, a second conductive layer 14, a common electrode layer 16 and a third conductive layer 18. The first and the second conductive layers 12 and 14, the common electrode layer 16 and the third conductive layer 18 are on the first substrate 11 and spaced from and insulated from each other. A first insulating layer 13 is between the first and the second conductive layers 12 and 14. A second insulating layer 15 is between the second conductive layer 14 and the common electrode layer 16. A planarization layer 17 is between the common electrode layer 16 and the third conductive layer 18.

Each of the first conductive layer 12, the first insulating layer 13, the second conductive layer 14, the second insulating layer 15, and the common electrode layer 16 bypasses the transparent area B1 and aligns with the display area A, and the first and second routing areas B21 and B22. An area of the planarization layer 17 in the transparent area B1 is in direct contact with the first substrate 11. The area of the planarization layer 17 aligned with the first routing area B21, the second routing area B22, and the display area A covers the common electrode layer 16. The third conductive layer 18 bypasses the transparent area B1 and the first routing area B21, and is aligned with the display area A and the second routing area B22.

As shown in FIG. 2, the array substrate 10 further includes photo spacers 19 in the first routing area B21. The photo spacers 19 are on a surface of the planarization layer 17 away from the first substrate 11. The photo spacers 19 can be arranged around the transparent area B1. In one embodiment, photo spacers 19 are arranged in the first routing area B21 adjacent to the transparent area B1, which improves the depression of the transparent area B1 and reduces the difference in cell gap between the transparent area B1 and the display area A. Furthermore, the imaging effect of the lens of the camera 60 is ensured, and the phenomenon of water ripples caused by uneven cell gap is avoided.

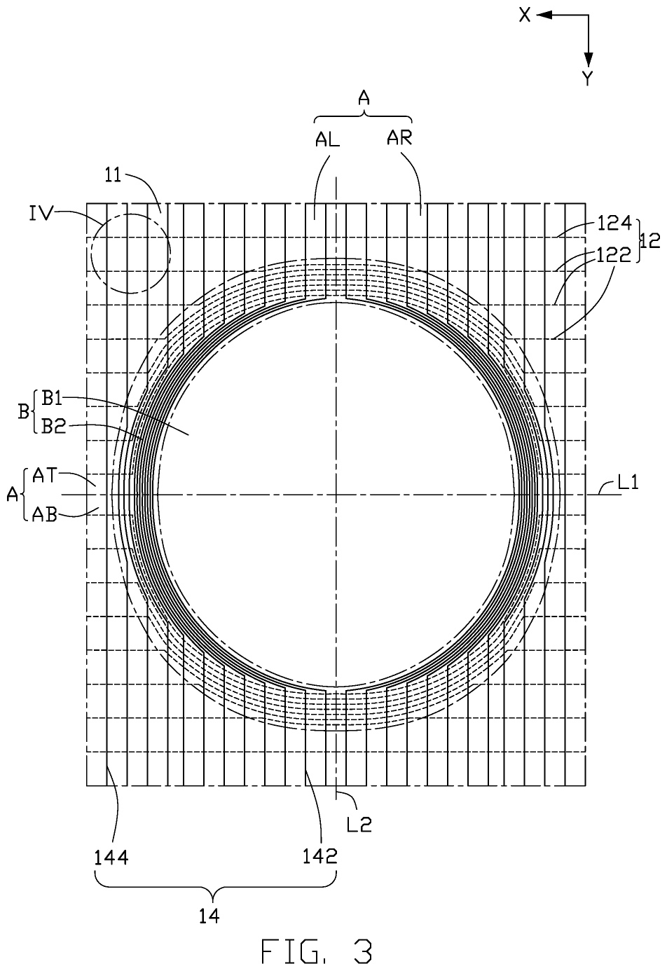

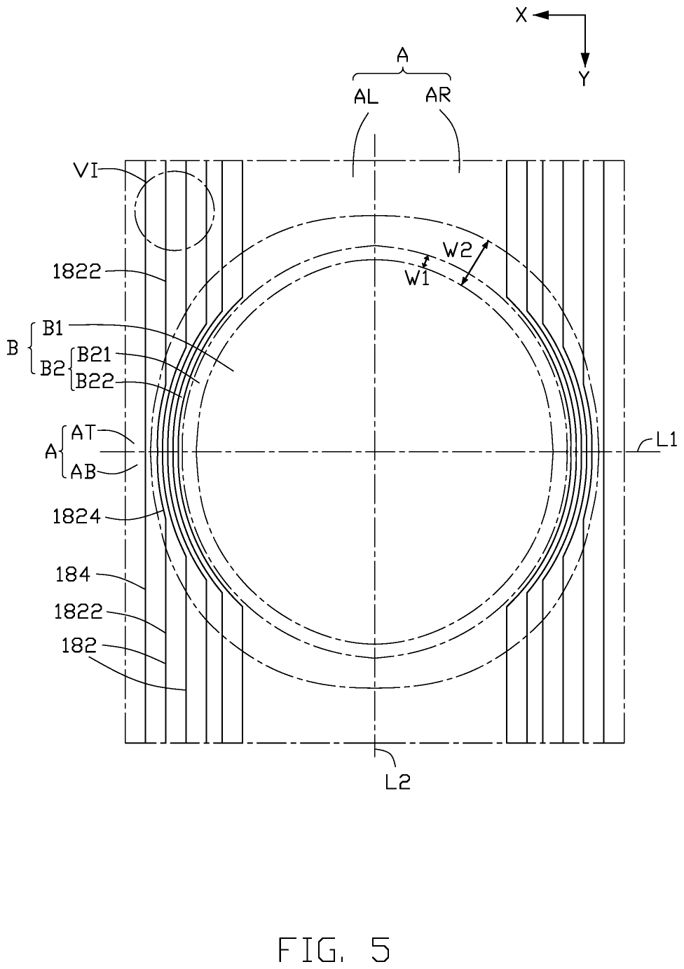

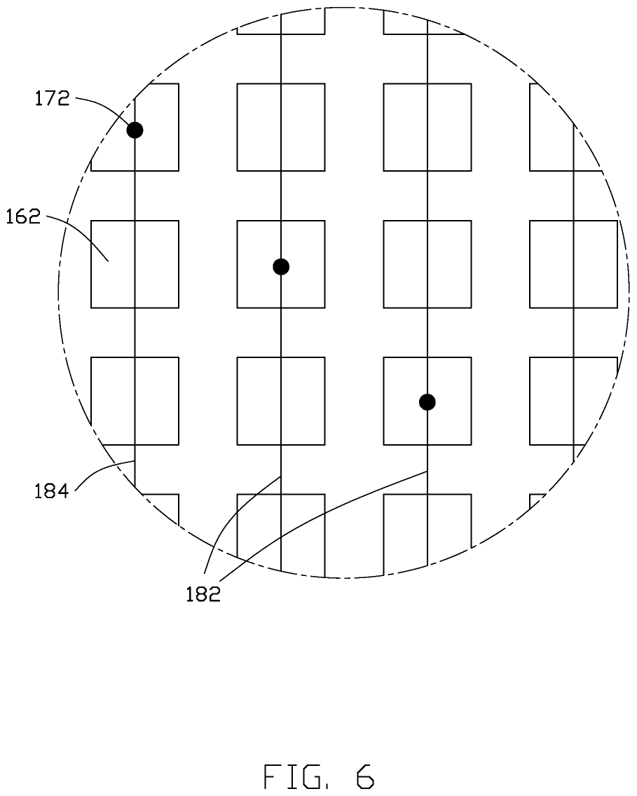

The first conductive layer 12 includes scan lines (as shown in FIG. 3). The second conductive layer 14 includes data lines (as shown in FIG. 3). The third conductive layer 18 includes first touch lines 182 and second touch lines 184 (as shown in FIG. 5). The common electrode layer 16 includes sub electrodes 162 (as shown in FIG. 6) spaced apart from each other. During a display period of a frame, each sub electrode 162 is configured to receive a common voltage and a touch driving voltage in a time division manner. That is, the array substrate 10 can be applied to an in-cell touch display panel 40.

As shown in FIG. 3, the routing area B2 has a first symmetry axis L1 and a second symmetry axis L2. In a first direction X, the routing area B2 is axially symmetrical with respect to the second symmetry axis L2. In a second direction Y, the routing area B2 is axially symmetrical with respect to the first symmetry axis L1. The second direction Y intersects with the first direction X. In the first direction X, the display area A is divided by the second symmetry axis L2 into a left area AL and a right area AR, on opposite sides of the second axis of symmetry L2. In the second direction Y, the display area A is divided by the first axis of symmetry L1 into an upper-side area AT and a lower-side area AB, on opposite sides of the first axis of symmetry L1. That is, the left and right areas AL and AR constitute the entire display area A. The upper area AT and the lower area AB constitute the entire display area A. The left area AL has areas overlapping with the upper area AT and the lower area AB. The upper area AR has areas overlapping with upper area AT and the lower area AB. In one embodiment, the second direction Y is perpendicular to the first direction X.

As shown in FIG. 3, the scan lines include first scan lines 122. The first scan lines 122 extend across the routing area B2 and are spaced apart from each other along the second direction Y. Some of the first scan lines 122 extend across the upper area AT and the routing area B2, and other first scan lines 122 extend across the lower area AB and the routing area B2. The first scan lines 122 are axially symmetrical with respect to the first symmetry axis L1.

Each first scan line 122 is axially symmetrical with respect to the second symmetry axis L2 in the routing area B2. Each first scan line 122 extends in the first direction X to the routing area B2 in the left area AL, bends around the peripheral contour of the transparent area B1 in the routing area B2, and extends along the first direction X in the right area AR. That is, each first scan line 122 bypasses the transparent area B1, crosses the routing area B2, and extends in the first direction X within the display area A. The first scan lines 122 in the upper area AT and the routing area B2 bend and extend along the upper half of the transparent area B1. The first scan lines 122 in the lower area AB and the routing area B2 bend and extend along the lower half of the transparent area B1.

Each first scan line 122 includes at least two straight portions and a curved portion. One straight portion of each first scan line 122 extends in the first direction X in the left-side area AL. The curved portion of each first scan line 122 extends around the peripheral contour of the transparent area B1 in the routing area B2 (appears as an arc in FIG. 3). The other straight portion of each first scan line 122 extends in the first direction X in the right area AR. A length of the curved portion of the first scan line 122 varies with a distance of the first scan line 122 from the first axis of symmetry L1. The closer the first scan line 122 is to the first axis of symmetry L1, the longer is the length of the curved portion. The further the first scan line 122 is from the first axis of symmetry L1, the shorter is the length of the curved portion. In one embodiment, the first scan lines 122 are equally spaced apart from each other.

As shown in FIG. 3, the scan lines further include second scan lines 124 only in the display area A. The second scan lines 124 extend only in the display area A, and do not extend to the routing area B2. Some of the second scan lines 124 are in the upper area AT, and the other second scan lines 124 are in the lower area AB. In the upper area AT, the second scan lines 124 are spaced apart from each other, and each second scan line 124 extends in the first direction X. In the lower area AB, the second scan lines 124 are spaced apart from each other, and each second scan line 124 extends in the first direction X. In the second direction Y, the first and the second scan lines 122 and 124 are arranged so that the second scan lines 124 are in the upper area AT, the first scan lines 122 are in the upper area AT, the first scan lines 122 are in the lower area AB, and the second scan lines 124 are in the lower area AB.

In an embodiment, in the left area AL (or the right area AR), along the second direction Y, there is one constant pitch between any two adjacent second scan lines 124, between any two adjacent first scan lines 122, and between the second scan line 124 and the adjacent first scan line 122.

As shown in FIG. 3, the data lines 14 includes first data lines 142 extending across the routing area B2. The first data lines 142 are spaced apart from each other in the first direction X. Some of the first data lines 142 extend in the left area AL and the routing area B2, and other first data lines 142 extend in the right area AR and the routing area B2. The first data lines 142 are axially symmetrical with respect to the second axis of symmetry L2.

A portion of each first data line 142 in the routing area B2 is axially symmetrical with respect to the first axis of symmetry L1. Each first data line 142 extends in the second direction Y to the routing area B2 in the upper area AT, bends around the peripheral contour of the transparent area B1 in the routing area B2, and extends in the second direction Y in the lower area AB. That is, each first data line 142 bypasses the transparent area B1, crosses the routing area B2, and extends in the second direction Y within the display area A. The first data lines 142 in the left area AL and the routing area B2 extend along the left half of the transparent area B1. The first data lines 142 in the right area AR and the routing area B2 bend and extend in the right half of the transparent area B1.

Each first data line 142 includes at least two straight portions and a curved portion. One straight portion of each first data line 142 extends in the second direction Y in the upper area AT. The curved portion of each first data line 142 extends around the peripheral contour of the transparent area B1 in the routing area B2 (shown as an arc in FIG. 3). The other straight portion of each first data line 142 extends in the second direction Y in the lower area AB. A length of the curved portion of each first data line 142 varies with a distance of the first data line 142 from the second axis of symmetry L2. The closer the first data line 142 is to the second axis of symmetry L2, the longer is the length of the curved portion. The further the first data line 142 is from the first axis of symmetry L1, the shorter is the length of the curved portion. In one embodiment, the first data lines 142 are equally spaced apart from each other.

As shown in FIG. 3, the data lines further includes second data lines 144 in the display area A. The second data lines 144 extend only in the display area A, and do not extend to the routing area B2. Some of the second data lines 144 are in the left area AL, and other second data lines 144 are in the right area AR. In the left area AL, the second data lines 144 are spaced apart from each other, and each second data line 144 extends along the second direction Y. In the right area AR, the second data lines 144 are spaced apart from each other, and each second data line 144 extends along the second direction Y.

In FIG. 3, none of the scan lines 12 and data lines 14 trespass in the camera area B, allowing light to pass through the camera area B without obstruction. A portion of each first scan line 122, each first data line 142, and each second data line 144 form a ring shape surrounding the transparent area B1. All the scan lines in the display area A extend along the first direction X, and all the data lines in the display area A extend along the second direction Y. The projection of each first data line 142 and each second data line 144 on the substrate overlaps with all of the first scan lines 122 and all of the second scan lines 124.

In one embodiment, images are not displayed in the camera area B. Any two adjacent first and second scan lines 122 and 124 and any two adjacent lines of the first and the second data lines 142 and 144 intersect in the display area A, thereby defining one sub-pixel 141.

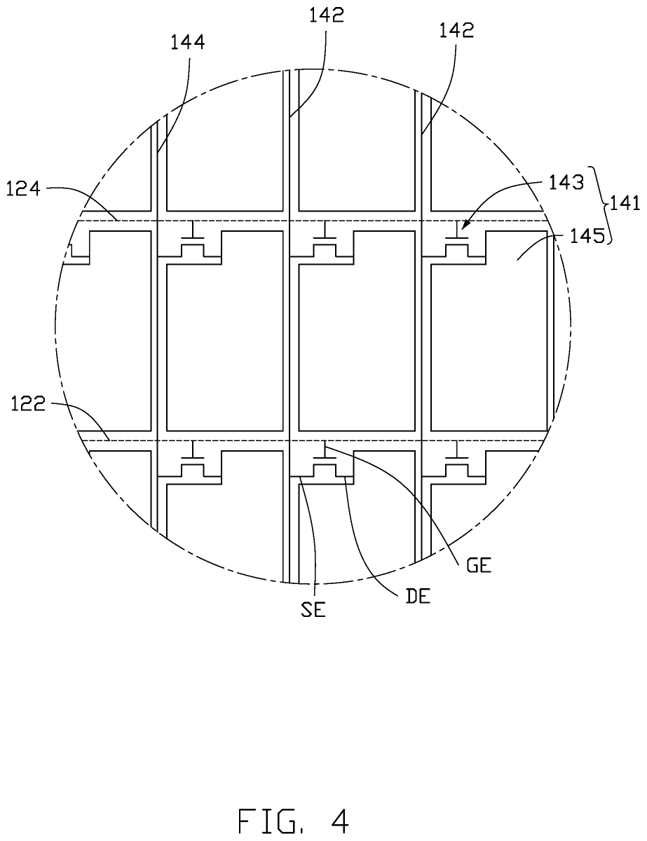

As shown in FIG. 4, each sub-pixel 141 includes a thin film transistor 143 and a pixel electrode 145. The thin film transistor 143 includes a gate electrode GE, a source electrode SE, and a drain electrode DE. The gate electrode GE is electrically connected to one of the first and second scan lines 122 and 124. The source electrode SE is electrically connected to one of the first and the second data lines 142 and 144. The drain electrode DE is electrically connected to the pixel electrode 145 in one sub-pixel 141.

As shown in FIG. 5, the first touch lines 182 are aligned with the second routing area B22 and are not in the first routing area B21. The first touch lines 182 are spaced apart from each other along the first direction X. Some of the first touch lines 182 extend in the left area AL and the second routing area B22, and other first touch lines 182 extend in the right area AR and the second routing area B22. The first touch lines 182 are axially symmetrical with respect to the second symmetry axis L2.

A portion of each first touch line 182 in the second routing area B22 is axially symmetrical with respect to the first symmetry axis L1. Each first touch line 182 extends along the second direction Y to the second routing area B22 in the upper side area AT, bends around the peripheral contour of the transparent area B1 in the second routing area B22, and extends in the second direction Y in the lower area AB. That is, each first touch line 182 bypasses the transparent area B1 and the first routing area B21, crosses the second routing area B22, and extends along the second direction Y in the display area A. The first touch lines 182 in the left area AL and the second routing area B22 extend along the left half of the transparent area B1, the first touch lines 182 in the right area AR and the second route area B22 extend along the right half of the transparent area B1.

Each first touch line 182 includes at least two straight portions 1822 and a curved portion 1824. One straight portion 1822 of each first touch line 182 extends in the second direction Y in the upper area AT. The curved portion 1824 of each first touch line 182 extends around the peripheral contour of the transparent area B1 in the routing area B2 (shown as an arc in FIG. 5). The other straight portion 1822 of each first touch line 182 extends in the second direction Yin the lower area AB. A length of the curved portion 1824 of each first touch line 182 varies with a distance of the first touch line 182 from the second axis of symmetry L2. The closer the first touch line 182 is to the second axis of symmetry L2, the longer is the length of the curved portion 1824. The further the first touch line 182 is from the first axis of symmetry L1, the shorter is the length of the curved portion 1824. In one embodiment, the first touch lines 182 are equally spaced apart from each other.

As shown in FIG. 5, the third conductive layer 18 further includes second touch lines 184 in the display area A. The second touch lines 184 extend only within the display area A, and do not extend to the routing area B2. Some of the second touch lines 184 are in the left area AL, and other second touch lines 184 are in the right area AR. In the left area AL, the second touch lines 184 are spaced apart from each other, and each second touch line 184 extends along the second direction Y. In the right area AR, the second touch lines 184 are spaced apart from each other, and each second touch line 184 extends along the second direction Y.

As shown in FIG. 6, the sub electrodes 162 are spaced apart from each other. The array substrate 10 further includes a driving circuit (not shown) for outputting voltages to the sub electrodes 162. The voltage can be a touch driving voltage and a common voltage. The sub electrodes 162 receive the touch signal voltage and the common voltage in a time division manner. When the sub electrodes 162 serve as electrodes, the sub electrodes 162 are configured to receive a touch driving voltage. When the sub electrodes 162 serve as common electrodes, the sub electrodes 162 are configured to receive a common voltage. Each sub electrode 162 is electrically connected to the driving circuit through at least one touch line (the first touch lines 182 or the second touch lines 184). The first touch lines 182 or the second touch lines 184 are electrically connected to the corresponding sub electrodes 162 through a via 172 extending through the planarization layer 17.

Referring to FIG. 3 and FIG. 5, both the first routing area B21 and the routing area B2 are circular. The first scan lines 122 formed by the first conductive layer 12 and the first data lines 142 formed by the second conductive layer 14 cover the entire routing area B2. The first touch lines 182 formed by the third conductive layer 18 cover the second routing area B22, but are not in the first routing area B21 adjacent to the transparent area B1.

As shown in FIG. 2, the photo spacers 19 are on the planarization layer 17 and are aligned with the first routing area B21. That is, the photo spacers 19 are on the surface of the planarization layer 17 which does not carry the first touch lines 182. In this way, the first touch lines 182 do not affect the flatness of the photo spacers 19. Furthermore, the photo spacers 19 are around the transparent area B1 in the camera area B, which avoids the problem of part of the film layers of the array substrate 10 (e.g., a thin film transistor array layer) not being present in the transparent area B1. The difference in cell gap between the transparent area B1 and that around the transparent area B1 is large, which would affect the display.

As shown in FIG. 5, a ring width of the first routing area B21 is defined as W1, and a ring width of the routing area B2 is defined as W2. In an embodiment, the ring width W1 of the first routing area B21 is at least one fifth in size of the ring width W2 of the routing area B2. That is, the area where the first touch lines 182 are located is at least one fifth of the ring width W2 of the routing area B2 from the transparent area B2, so that there is sufficient space to ensure that the photo spacers 19 can be directly formed on the planarization layer 17. In addition, in the display area A, the array substrate 10 may carry a main photo spacer to maintain a gap between the array substrate 10 and the color filter substrate 20. In one embodiment, the photo spacers 19 are in the first routing area B21 adjacent to the transparent area B1, so that support for the display area A and for the camera area B is similar and sufficient.

In one embodiment, the first substrate 11 is made of a transparent hard material, such as glass, quartz, or plastic. In other embodiments, the first substrate 11 can be made of a flexible material, such as one or more of polyethersulfone (PES), polyethylene naphthalate (PEN), polyethylene (PE), and polyimide (PI), polyvinyl chloride (PVC), and polyethylene terephthalate (PET). The first, the second, and the third conductive layers 12, 14, and 18 are made of at least one material selected from the group consisting of aluminum, silver, gold, chromium, copper, indium, manganese, molybdenum, nickel, neodymium, palladium, platinum, titanium, tungsten, and zinc. The first insulating layer 13, the second insulating layer 15, and the planarization layer 17 may be made of silicon oxide (SiOx), silicon nitride (SiNx), and/or silicon oxynitride (SiOxNy).

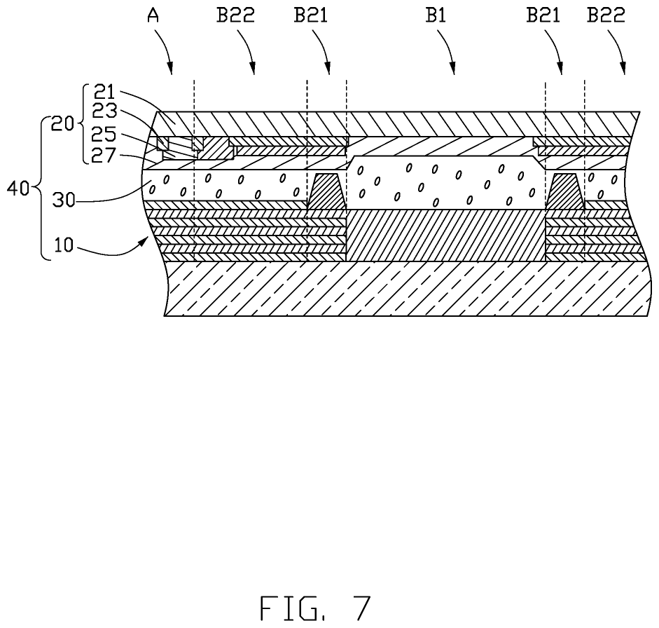

FIG. 7 shows a display panel 40 according to an embodiment. The display panel 40 includes the array substrate 10 and a color filter substrate 20 opposite to the array substrate 10. A liquid crystal layer 30 is between the array substrate 10 and the color filter substrate 20.

The color filter substrate 20 includes a transparent second substrate 21, a black matrix 23, and a color filter layer 25 on a side of the second substrate 21 close to the liquid crystal layer 30. The black matrix 23 and the color filter layer 25 are around the transparent area B1, that is, they are not present in the transparent area B1.

The color filter substrate 20 further includes an overcoat layer 27. The overcoat layer 27 is on a side of the black matrix 23 and the color filter layer 25 away from the second substrate 21. A portion of the cover layer 27 in the transparent area B1 is in direct contact with the second substrate 21. A portion of the cover layer 27 in the transparent area B1 is recessed toward the second substrate 21 with respect to a portion thereof in the display region A.

As shown in FIG. 7, only the planarization layer 17 remains on the first substrate 11 in the transparent area B1 and only the overcoat layer 27 remains on the second substrate 21 in the transparent area B1. Since the display panel 40 is aligned with a part of the structure of the transparent area B1 (e.g., the part which does not include the black matrix 23 and the color filter layer 25), the first substrate 11 or the second substrate 21 in the transparent area B1 can be easily recessed.

In one embodiment, photo spacers 19 are provided in the first routing area B21 adjacent to the transparent area B1, canceling the depression of the transparent area B1 and reducing the difference in cell gap between the transparent area B1 and the the display area A. Furthermore, the imaging effect of the camera 60 is ensured, and the phenomenon of water ripples caused by an uneven cell gap is avoided.

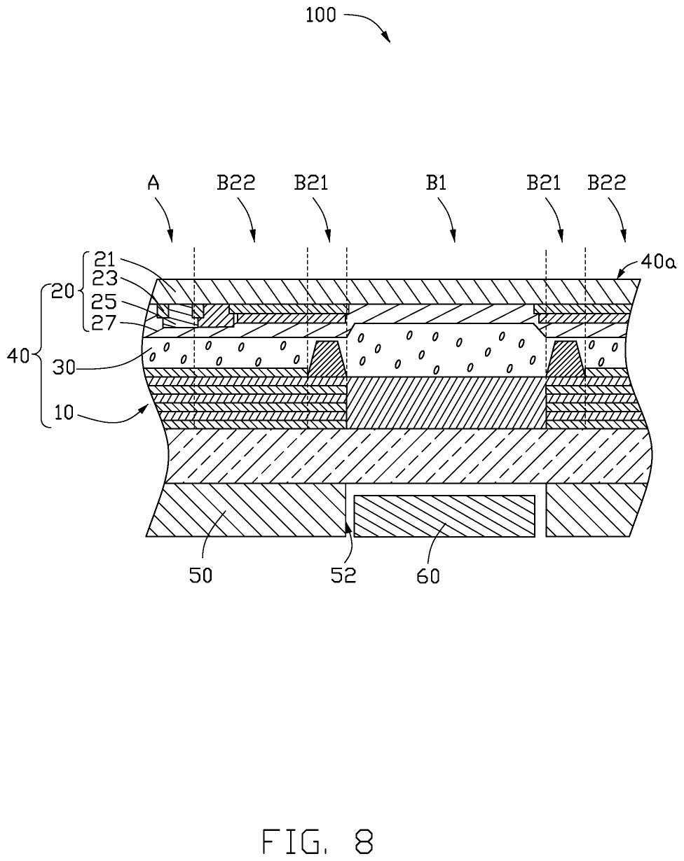

FIG. 8 shows a display device 100 according to an embodiment. The display device 100 includes a display panel 40, a backlight module 50, and a camera 60. The display panel 40 has a display surface 40a. The camera 60 is on a side of the display panel 40 away from the display surface 40a. The camera 60 is in the camera area B to collect light through the camera area B.

The backlight module 50 is a direct type backlight. The backlight module 50 includes a light source (not shown), an optical film group (not shown), a back plate (not shown), and the like. The backlight module 50 defines a mounting hole 52 extending through the backlight module 50 in the camera area B. A size of the mounting hole 52 is larger than or substantially equal to a size of the camera area B. The camera 60 is in the mounting hole 52. As the camera 60 is arranged in the camera area B surrounded by the display area A, there is no need to open a through hole in a border area of the display panel for placement of the camera. The border of the display device 100 can therefore be narrow or even non-existent, increasing a screen-to-body ratio of the display device 100. In one embodiment, the display device 100 may be a mobile phone, a tablet computer, or the like.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. An array substrate defining a display area and a camera area surrounded by the display area, the camera area defining a transparent area and a routing area surrounding the transparent area, the routing area defining a first routing area adjacent to and surrounding the transparent area and a second routing area surrounding the first routing area, the array substrate comprising:
a first substrate;
a first conductive layer on the first substrate, the first conductive layer comprising a plurality of first scan lines spaced apart from each other;
a second conductive layer on the first conductive layer, the second conductive layer comprising a plurality of first data lines spaced apart from each other;
a common electrode layer on the second conductive layer, the common electrode layer comprising a plurality of sub electrodes spaced apart from each other, each of the plurality of sub electrodes being configured to receive a common voltage and a touch driving voltage in a time division manner during a display period of a frame;
a third conductive layer on the common electrode layer, the third conductive layer comprising a plurality of first touch lines spaced apart from each other, each of the plurality of first touch lines being electrically connected to at least one of the plurality of sub electrodes;
a planarization layer between the common electrode layer and the third conductive layer, the planarization layer in the transparent area being in direct contact with the first substrate, the planarization layer in the routing area and the display area covering the common electrode layer; and
a photo spacer on a surface of the planarization layer away from the first substrate, the photo spacer being in the first routing area;
wherein the third conductive layer is on a surface of the planarization layer away from the first substrate, and the third conductive layer bypasses the transparent area and the first routing area, and is in the second routing area and the display area.

2. The array substrate according to claim 1, wherein both the first routing area and the routing area are circular, and a ring width of the first routing area is at least one fifth of the routing area.

3. The array substrate according to claim 1, wherein each of the plurality of first scan lines bypasses the transparent area, crosses the routing area, and extends along a first direction in the display area;
each of the plurality of first data lines bypasses the transparent area, crosses the routing area, and extends along a second direction in the display area;
the second direction intersects with the first direction; and
each of the plurality of first touch lines bypasses the transparent area and the first routing area, crosses the second routing area, and extends along the second direction in the display area.

4. The array substrate according to claim 3, wherein each of the plurality of first scan lines, each of the plurality of first data lines, and each of the plurality of first touch lines comprises a curved portion extending around the transparent area.

5. The array substrate according to claim 4, wherein the third conductive layer further comprises a plurality of second touch lines, each of the plurality of second touch lines extends in the second direction in the display area, and each of the plurality of second touch lines is electrically connected to at least one of the plurality of sub electrodes.

6. The array substrate according to claim 5, wherein the first conductive layer further comprises a plurality of second scan lines, and each of the plurality of second scan lines extends in the first direction in the display area;
the second conductive layer further comprises a plurality of second data lines, and each of the plurality of second data lines extends in the second direction in the display area.

7. The array substrate according to claim 6, wherein any two adjacent ones of the plurality of the first scan lines, the plurality of second scan lines and any two adjacent ones of the plurality of the first data lines, the plurality of second data lines intersect in the display area to define one sub pixel;
the sub-pixel comprises a thin film transistor and a pixel electrode;
the thin film transistor comprises a gate electrode, a source electrode, and a drain electrode;
the gate electrode is electrically connected to one of the plurality of first scan lines and the plurality of second scan lines, and the source electrode is electrically connected to one of the plurality of first data lines and the plurality of second data lines, the drain electrode is electrically connected to the pixel electrode.

8. A display panel comprising a color filter substrate, an array substrate, and a liquid crystal layer between the color filter substrate and the array substrate, the array substrate defining a display area and a camera area surrounded by the display area, the camera area defining a transparent area and a routing area surrounding the transparent area, the routing area defining a first routing area adjacent to and surrounding the transparent area and a second routing area surrounding the first routing area, the array substrate comprising:
a first substrate;
a first conductive layer on the first substrate, the first conductive layer comprising a plurality of first scan lines spaced from each other;
a second conductive layer on the first conductive layer, the second conductive layer comprising a plurality of first data lines spaced from each other;
a common electrode layer on the second conductive layer, the common electrode layer comprising a plurality of sub electrodes spaced from each other, each of the plurality of sub electrodes being configured to receive a common voltage and a touch driving voltage in a time division manner during a display period of a frame;
a third conductive layer on the common electrode layer, the third conductive layer comprising a plurality of first touch lines spaced from each other, each of the plurality of first touch lines being electrically connected to at least one of the plurality of sub electrodes;
a planarization layer between the common electrode layer and the third conductive layer, the planarization layer in the transparent area being in direct contact with the first substrate, the planarization layer in the routing area and the display area covering the common electrode layer; and
a photo spacer on a surface of the planarization layer away from the first substrate, the photo spacer being in the first routing area;
wherein the third conductive layer is on a surface of the planarization layer away from the first substrate, and the third conductive layer bypasses the transparent area and the first routing area, and is in the second routing area and the display area.

9. The display panel according to claim 8, wherein the color filter substrate comprises a second substrate and a black matrix and a color filter layer on a side of the second substrate close to the liquid crystal layer;
both the black matrix and the color filter layer bypass the transparent area.

10. The display panel according to claim 8, wherein both the first routing area and the routing area are circular, and a ring width of the first routing area is at least one fifth of the routing area.

11. The display panel according to claim 8, wherein each of the plurality of first scan lines bypasses the transparent area, crosses the routing area, and extends along a first direction in the display area;
each of the plurality of first data lines bypasses the transparent area, crosses the routing area, and extends along a second direction in the display area;
the second direction intersects with the first direction; and
each of the plurality of first touch lines bypasses the transparent area and the first routing area, crosses the second routing area, and extends along the second direction in the display area.

12. The display panel according to claim 11, wherein each of the plurality of first scan lines, each of the plurality of first data lines, and each of the plurality of first touch lines comprises a curved portion extending around the transparent area.

13. The display panel according to claim 12, wherein the third conductive layer further comprises a plurality of second touch lines, each of the plurality of second touch lines extends in the second direction in the display area, and each of the plurality of second touch lines is electrically connected to at least one of the plurality of sub electrodes.

14. The display panel according to claim 13, wherein the first conductive layer further comprises a plurality of second scan lines, and each of the plurality of second scan lines extends in the first direction in the display area;
the second conductive layer further comprises a plurality of second data lines, and each of the plurality of second data lines extends in the second direction in the display area.

15. The display panel according to claim 14, wherein any two adjacent ones of the plurality of the first scan lines, the plurality of second scan lines and any two adjacent ones of the plurality of the first data lines, the plurality of second data lines intersect in the display area to define one sub pixel;
the sub-pixel comprises a thin film transistor and a pixel electrode;
the thin film transistor comprises a gate electrode, a source electrode, and a drain electrode;
the gate electrode is electrically connected to one of the plurality of first scan lines and the plurality of second scan lines, and the source electrode is electrically connected to one of the plurality of first data lines and the plurality of second data lines, the drain electrode is electrically connected to the pixel electrode.

16. A display device, comprising:
a display panel comprising a color filter substrate, an array substrate, and a liquid crystal layer between the color filter substrate and the array substrate, the array substrate defining a display area and a camera area surrounded by the display area, the camera area defining a transparent area and a routing area surrounding the transparent area, the routing area defining a first routing area adjacent to and surrounding the transparent area and a second routing area surrounding the first routing area, the display panel comprising a display surface for displaying images; and a backlight module, the backlight module is on a side of the display panel away from the display surface, the backlight module defining a mounting hole extending through the backlight module, and the mounting hole being in the transparent area; and
a camera in the mounting hole to collect image information through the transparent area;
the array substrate comprising:
a first substrate;
a first conductive layer on the first substrate, the first conductive layer comprising a plurality of first scan lines spaced from each other;
a second conductive layer on the first conductive layer, the second conductive layer comprising a plurality of first data lines spaced from each other;
a common electrode layer on the second conductive layer, the common electrode layer comprising a plurality of sub electrodes spaced from each other, each of the plurality of sub electrodes being configured to receive a common voltage and a touch driving voltage in a time division manner during a display period of a frame;
a third conductive layer on the common electrode layer, the third conductive layer comprising a plurality of first touch lines spaced from each other, each of the plurality of first touch lines being electrically connected to at least one of the plurality of sub electrodes;
a planarization layer between the common electrode layer and the third conductive layer, the planarization layer in the transparent area being in direct contact with the first substrate, the planarization layer in the routing area and the display area covering the common electrode layer; and
a photo spacer on a surface of the planarization layer away from the first substrate, the photo spacer being in the first routing area;
wherein the third conductive layer is on a surface of the planarization layer away from the first substrate, and the third conductive layer bypasses the transparent area and the first routing area, and is in the second routing area and the display area.

17. The display device according to claim 16, wherein the color filter substrate comprises a second substrate and a black matrix and a color filter layer on a side of the second substrate close to the liquid crystal layer;
both the black matrix and the color filter layer bypass the transparent area.

18. The display device according to claim 16, wherein both the first routing area and the routing area are circular, and a ring width of the first routing area is at least one fifth of the routing area.

19. The display device according to claim 18, wherein each of the plurality of first scan lines bypasses the transparent area, crosses the routing area, and extends along a first direction in the display area;
each of the plurality of first data lines bypasses the transparent area, crosses the routing area, and extends along a second direction in the display area;
the second direction intersects with the first direction; and
each of the plurality of first touch lines bypasses the transparent area and the first routing area, crosses the second routing area, and extends along the second direction in the display area.

20. The display device according to claim 19, wherein each of the plurality of first scan lines, each of the plurality of first data lines, and each of the plurality of first touch lines comprises a curved portion extending around the transparent area.
